(19) United States
(12) Patent Application Publication
(10) Pub. No.: US 2009/0153133 A1
(43) Pub. Date: Jun. 18, 2009

(54) METHODS AND APPARATUS FOR COLLECTING CHARACTERISTICS OF A POWER LINE A BPL SYSTEM

(76) Inventor: Michael Keselman, San Ramon, CA (US)

Correspondence Address: DICKSTEIN SHAPIRO LLP, 1825 EYE STREET NW, Washington, DC, 20006-5403, US

(21) Appl. No.: 12/333,825

(22) Filed: Dec. 12, 2008

Related U.S. Application Data
(60) Provisional application No. 60/996,983, filed on Dec. 13, 2007.

(51) Int. Cl. G01R 19/00; H02J 3/02; G01R 25/00

(52) U.S. Cl. 324/86; 307/3; 324/76.11

(57) ABSTRACT

An apparatus for collecting characteristics of a power line in a broadband over power line system that comprises a power line characteristic measuring device for measuring power line characteristics and a collector unit for collecting data from the power line characteristic measuring device and sending the data over the broadband over power line system to a remote location where the collector unit is a regenerator. Further, the apparatus can comprise a coupler, to couple the power line to the power line characteristic measuring device and the collector unit and allows a broadband over power line signal to pass from the power line to the collector unit.

### CROSS-REFERENCE TO RELATED APPLICATIONS

This application claims the benefit of U.S. Provisional Appl. No. 60/996,983 filed Dec. 13, 2007, the entire disclosure of which is incorporated herein by reference.

### FIELD OF THE INVENTION

The invention is directed toward measuring characteristic data of a power line in a broadband over power line (BPL) system.

### BACKGROUND OF THE INVENTION

Broadband communications services can be provided using one or more high-voltage cables of a power distribution network, while the power distribution network supplies electrical power. A radio-frequency signal at a first location (or node) is modulated with a data signal and coupled to a high-voltage power line serving as a transmission channel. At a second node, the radio-frequency signal is coupled from the high-voltage cable to a demodulator for converting the modulated signal back to a data signal. Data is sent from the second node to the first node in a similar manner typically using a different band of frequencies. This full-duplex broadband service between the locations may simultaneously supply a variety of communication needs, such as telephone service, video service, Internet service, and other services requiring high-speed data transfers.

The data signal of a BPL system degrades to some extent as the signal travels over the power lines. In order to maintain the signal, regenerators or repeaters are used at certain points between the modulation and demodulation of the BPL signal. The regenerators or repeaters maintain the fidelity of the signal over longer distances.

Since data can be sent over the power line, various “smart grid” systems have been used. Such systems may read a customer's electric power meter remotely or even remotely manipulate devices at the customer site. Another use of such systems is to read various characteristics of the power line itself. Conventionally, power companies read the characteristics of power lines using low-voltage metering devices. Since the metering devices are typically low-voltage, a transformer is installed to couple the metering devices to power lines. Transformers are large bulky devices and fairly expensive. In addition, the power company must provide a communication link between the metering device and the operator or data collection device. The availability and cost of the communication link and transformer can vary greatly, which may limit the ability to install metering devices throughout the electric grid. Thus, power companies have to install additional costly transformers and communication links to monitor the power gird for potential power outages.

Accordingly, there is a need and desire for collecting data on characteristics of a power line to identify and locate potential power outages without resorting to transformers and costly communication links.

### BRIEF SUMMARY OF THE INVENTION

The present invention meets the afore-described deficiencies. In one embodiment, the present invention includes an apparatus for collecting characteristics of a power line in a broadband over power line system comprising a power line characteristic measuring device for measuring power line characteristics. The apparatus further comprises a collector unit for receiving data from the power line characteristic measuring device and sending the data over the broadband over power line system to a remote location, wherein the collector unit comprises a regenerator. The apparatus can further comprise a coupler, to couple the power line to the power line characteristic measuring device and the collector unit, that allows a broadband over power line signal to pass from the power line to the collector unit. The coupler can also allow for a representative voltage, a representative phase angle, or a representative current of the power line to be measured by the power line characteristic measuring device.

In another embodiment, the invention comprises a method of collecting information on characteristics of a power line in a broadband over power line system comprising obtaining information on the characteristics of the power line using a collector unit and sending the information over the broadband over power line system to a remote location.

### BRIEF DESCRIPTION OF THE DRAWINGS

FIG. 1 is a block diagram of a prior art BPL system;

FIG. 2 is a block diagram of a BPL system for measuring characteristics of a power line constructed in accordance with an embodiment described herein;

FIG. 3 is a block diagram of a BPL system wherein an embodiment of the present invention for measuring characteristics of a power line is interfaced with various external devices;

FIG. 4 is a block diagram of a BPL system wherein an embodiment of the present invention for measuring characteristics of a power line is interfaced with a three phase electric system;

FIG. 5 is a block diagram of a BPL system wherein an embodiment of the present invention for measuring characteristics of a power line is interfaced with a voltage reader;

FIG. 6 is a block diagram of a BPL system with a collector unit for collecting characteristic data about a power line constructed in accordance with an embodiment described herein.

### DETAILED DESCRIPTION OF THE INVENTION

In the following detailed description, reference is made to the accompanying drawings, which form a part hereof and show by way of illustration specific embodiments of the present invention. These embodiments are described in sufficient detail to enable those skilled in the art to practice them, and it is to be understood that other embodiments may be utilized, and that structural, logical, processing, and electrical changes may be made.

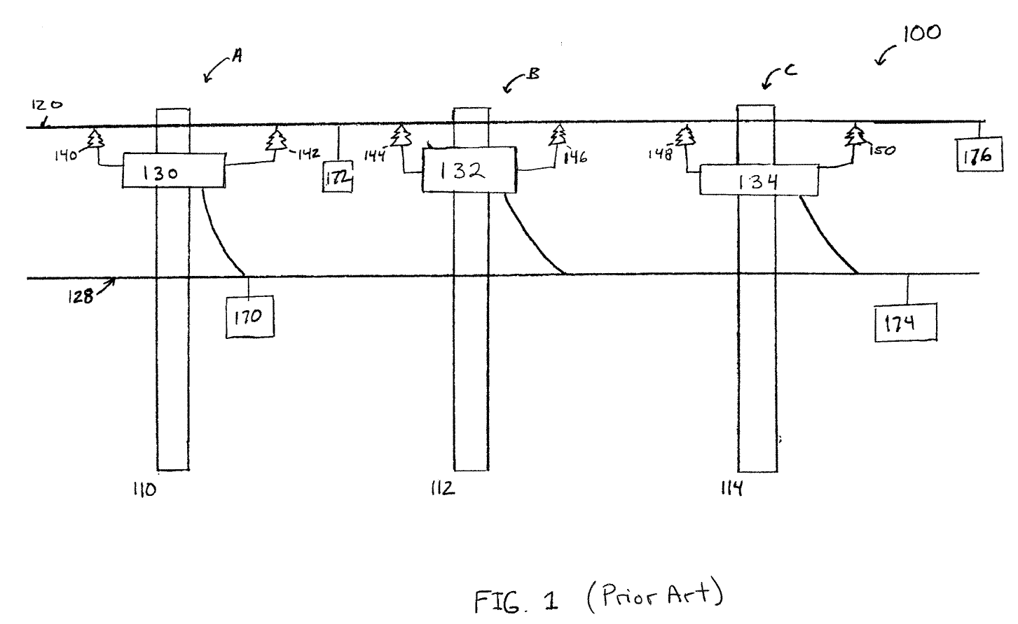

FIG. 1 shows a block diagram of a prior art BPL system 100. BPL system 100 includes first, second, and third utility poles 110, 112, 114; a medium-voltage power line 120; a low-voltage power line 128; first, second and third regenerators 130, 132, 134. First through sixth couplers 140, 142, 144, 146, 148 and 150 are connected between regenerators 130, 132, 134 and medium-voltage power line 120. BPL system 100 further includes components 170, 172, 174, 176, which can be any typical components found in a power grid and connected to any part of the grid, e.g., transformers, arresters, reclosers, and taps. Moreover, each utility pole 110, 112, 114 connected to a respective regenerator 130, 134, 138 is a node A, B, C. Each node has two couplers 140, 142, 144, 146, 148, and 150 connected to it. BPL system 100 is for providing broadband communication services.

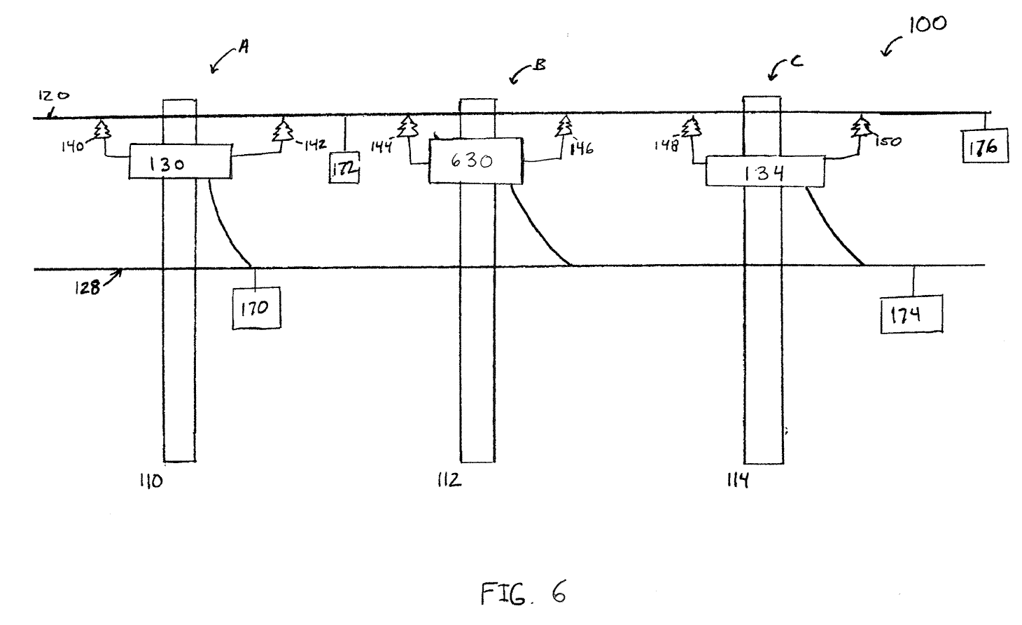

FIG. 6 shows an embodiment of the invention using BPL system 100, where regenerator 132 has been replaced with a collector unit 630 that includes a regenerator. Collector unit 630 uses the elements of a BLP system to monitor and collect characteristic data of medium voltage line 120. Thus, collector unit 630 provides power companies a way to monitor a voltage line without the high additional cost of transformers and communications links.

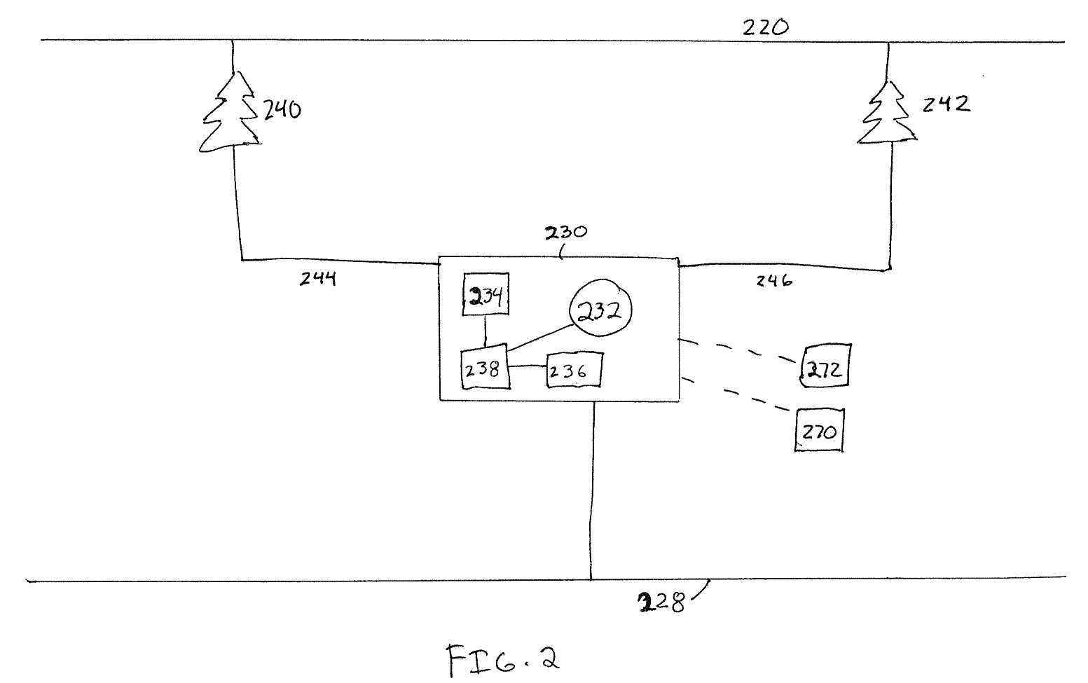

FIG. 2 is a schematic diagram of a BPL system node wherein collector unit 230 obtains characteristics of a power line constructed in accordance with an embodiment described herein. Collector unit 230 contains a regenerator 232, a power line characteristic measuring device 234, a memory 236 and a processor 238. Processor 238 is connected to and controls power line characteristic measuring device 234 and memory 236. Processor 238 can be any device capable of following instructions for receiving and outputting data. Processor 238 is also connected to regenerator 232. Couplers 240 and 242 are coupled to medium voltage line 220. Coupler 240 is connected to collector unit 230 by line 244 and coupler 242 is connected to collector unit 230 by line 246. Collector unit 230 is also connected to a low voltage line 228 and external devices 270 and 272.

In this embodiment, coupler 240 of the BPL system is a capacitive coupler configured as a voltage divider. An example of a capacitive coupler used can be found in U.S. patent application Ser. No. 12/268,214, filed Nov. 10, 2008, the contents of which are incorporated herein by reference. Coupler 240 allows the BPL signal to pass from medium voltage line 220 to collector unit 230 on line 244. Further, coupler 240 maintains a low voltage corresponding to the voltage of medium voltage line 220 on line 244. Power line characteristic measuring device 234, in this embodiment is a volt meter and measures the voltage on line 244. Power line characteristic measuring device 234 is a low-voltage volt meter because the coupler 240 maintains a low voltage on line 244 that corresponds to the higher voltage of medium voltage line 220. The measurement of power line characteristic measuring device 234 is sent to processor 238 through a standard interface such as RS-232, USB or Ethernet.

Processor 238 sends the voltage measurement or characteristic data to one or more remote locations (not shown) once the data is received from power line characteristic measuring device 234. Further, processor 238 can be programmed to store the characteristic data in memory 236 for a certain period of time and then send the data to one or more remote locations. Memory 236 can be a solid state memory such as flash or a volatile type memory such as DRAM. In addition, processor 238 can store the characteristic data in memory 236 until a signal is received to send the characteristic data to one or more remote locations. Processor 238 does not necessarily save or send all the characteristic data received from the power line characteristic measuring device 234. Only a sampling of the data received by processor 238 can be saved or sent to a remote location. Further functions and operations can be performed by processor 238, such as, but not limited to, averaging the measured voltages over time and sending alerts if the measured voltage crosses a set threshold.

Processor 238 can be pre-programmed with instructions to perform the above mentioned operations with the characteristic data. In addition, processor 238 can be operated remotely and perform operations based on received instructions.

Collector unit 230 can also be interfaced with external devices 270 and 272, via wireless interface, a wired interface, or other appropriate interface known in the art. External devices 270 and 272 can be other BPL system components or other devices including, but not limited to, another BPL coupler, other characteristic measurement equipment, a wireless transmitter or other communication devices. Collector unit 230 can be interfaced with external devices 270 and 272 using interfaces known to the industry, including, but not limited to Ethernet (IEEE standard 802.3), serial interfaces (such as RS-232, EIA-422, RS-485), or SCADA protocols (such as Modbus, RP-570, DNP3, IEC-60870-5-101, IEC-60870-5-104, IEC-61850, Profibus).

Characteristic data collected by collector unit 230 is sent to a remote location (not shown) over the BPL system using regenerator 232. A regenerator, such as regenerator 232, is a specialized communication device that receives data, modulates the data and then transmits the data over a BPL line. A regenerator can also receive and demodulate data. An example regenerator that could be used in this system is part number BRU sold by International Broadband Electric Communications, Inc. (“IBEC”), located at 285 Dunlop Boulevard SW, Suite K, Huntsville, Ala., 35824. To send the data to a remote location, processor 238 first sends the data to regenerator 232. Regenerator 232 receives the characteristic data from processor 238, modulates the data and sends the data over the BPL system to a remote location. Regenerator 232 can also receive instructions for processor 238 from a remote location. Upon receiving the instructions, regenerator 232 demodulates the instructions and sends them to processor 232. Thus, collector unit 230 uses regenerator 232 to send the characteristic data and no additional communication link is needed.

Characteristic data collected by collector unit 230 can be sent to a remote location (not shown) in other various ways. For example, external device 270 can be any type of communication device and send the data that it receives from collector unit 230 to a remote location. In this instance, external device 270 is a wireless transmitter that sends the data to a remote location.

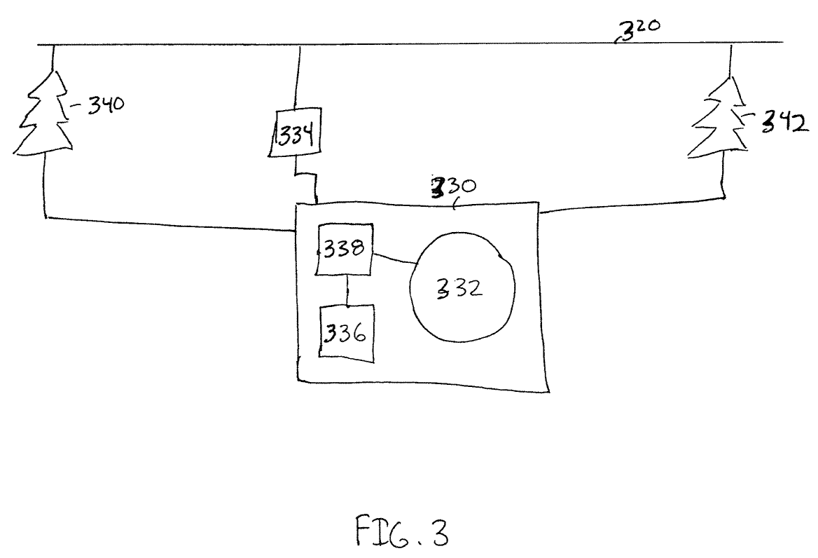

FIG. 3 is a schematic diagram of a BPL system node wherein collector unit 330 collects and transmits characteristics of a power line constructed in accordance with an embodiment described herein. Collector unit 330 contains a regenerator 332, a processor 338 and a memory unit 336. Couplers 340 and 342 are coupled to medium voltage line 320 and collector unit 330. A voltage meter 360 is coupled to medium voltage line 320 and collector unit 330, and controlled by collector unit 330.

Voltage meter 334 in this embodiment is not part of the collector unit. In this embodiment, voltage meter 334 measures the voltage of medium voltage line 320. Voltage meter 334 sends the voltage measurement to collector unit 330. Processor 338 receives the voltage measurement and regenerator 332 sends the measurement to a remote location.

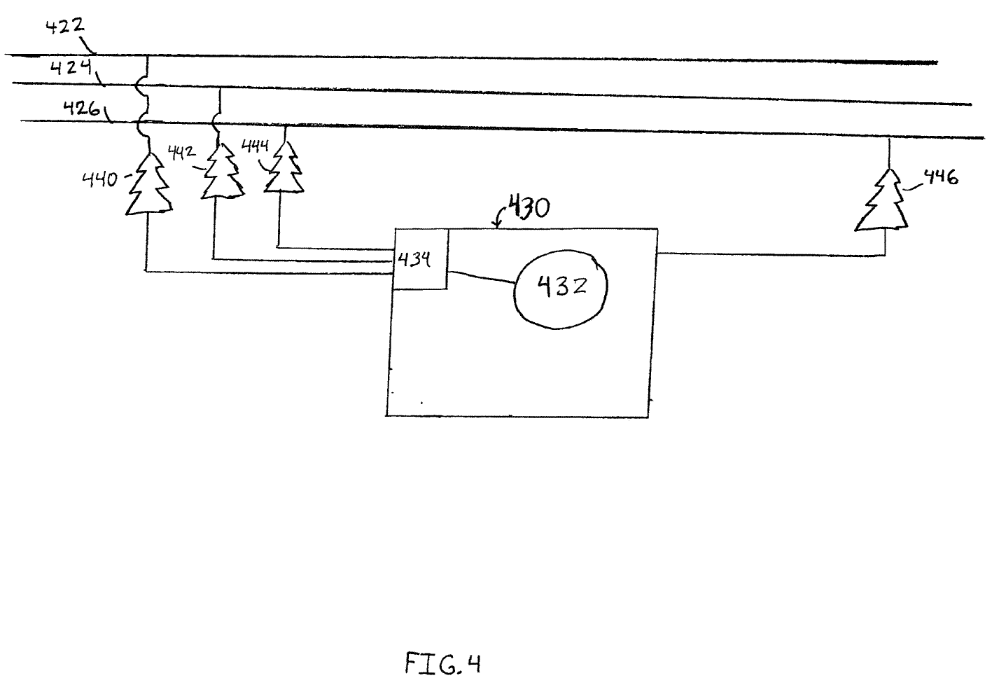

FIG. 4 is a schematic diagram of a BPL system node wherein collector unit 430 obtains characteristics of a power line constructed in accordance with an embodiment described herein. Collector unit 430 contains regenerator 432 and voltage meter 434. In this embodiment, regenerator 432 comprises an additional processor and memory unit which perform the functions similar to those of processor 238 and memory 236 described in FIG. 2. Regenerator 432 is connected to and controls voltage meter 460. Couplers 440, 442, 444, and 446 are coupled to collector unit 430 and coupler 440 is coupled to medium voltage line 422, coupler 442 is coupled to the medium voltage lines 424, and coupler 444 is coupled to medium voltage lines 426. Medium voltage lines 422, 424, 426 comprise a three phase electrical system. Coupler 440 is designed to be a voltage divider and allow for voltage meter 460 to determine a representative phase of medium voltage line 422. Couplers 442 and 444 are similarly designed.

Voltage meter 460 measures representative phase angles and voltages of medium voltage lines 422, 424, and 426. The phase angle and voltages measurements are sent to regenerator 432 and represent characteristic data of medium voltage lines 422, 424, and 426. Regenerator 432 sends the characteristic data composed of the voltages and phase angles measurements of the medium power lines 422, 424, and 426 to one or more remote locations (not shown) over the medium power line 426.

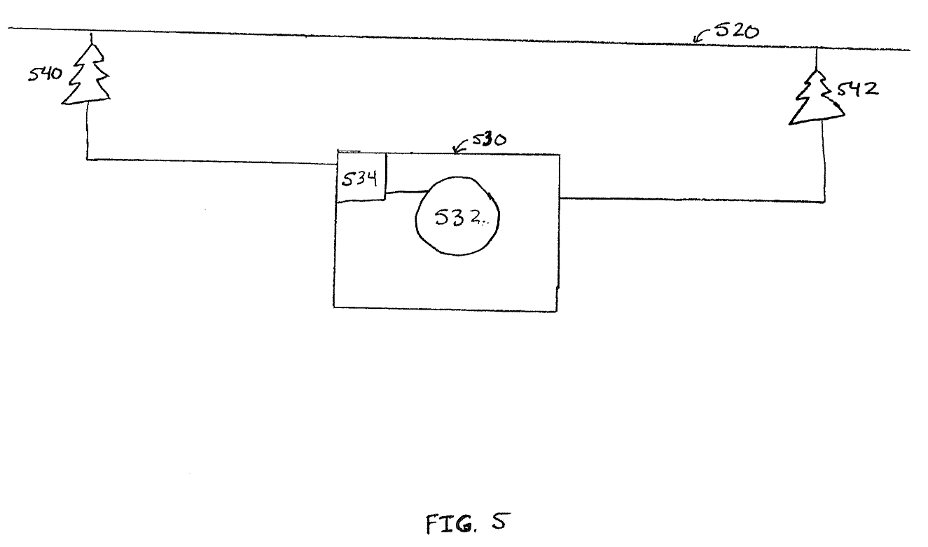

FIG. 5 is a schematic diagram of a BPL system node wherein collector unit 530 obtains characteristics of a power line constructed in accordance with an embodiment described herein. Collector unit 530 contains a regenerator 532 and a current meter 534. In this embodiment, regenerator 532 comprises a processor and memory unit which perform the functions of processor 238 and memory 236 of the embodiment described in FIG. 2. Within collector unit 530, regenerator 532 is connected to and controls current meter 534. Couplers 540 and 542 are coupled to medium voltage line 520 and collector unit 530. In this embodiment, coupler 540 is an inductive coupler and provides a current to current meter 534 related to the current of medium voltage line 520. Regenerator 530 sends the characteristic data to one or more remote locations (not shown) over the power medium power line 426.

The processes and devices in the above description and drawings illustrate a few examples of many methods and devices that could be used and produced to achieve the objects, features, and advantages of embodiments described herein. For example, an inductive coupler can be used in place of a capacitive coupler in FIG. 2. Further, more than one type of coupler may be coupled to a collector unit to assist in providing measurements of a power line's characteristic data. Thus, the embodiments are not to be seen as limited by the foregoing description of the embodiments, but only limited by the appended claims.

What is claimed as new and desired to be protected by a Patent of the United States is:

1. An apparatus for collecting characteristics of a power line in a broadband over power line system comprising:
a power line characteristic measuring device for measuring power line characteristics; and
a collector unit for receiving data from the power line characteristic measuring device and sending the data over the broadband over power line system to a remote location.

2. The apparatus of claim 1, wherein the collector unit comprises a processor for collecting data from the power line characteristic measuring device and a regenerator for sending information over the broadband over power line system.

3. The apparatus of claim 1, wherein the collector unit comprises a regenerator.

4. The apparatus of claim 1, further comprising a coupler to couple the power line to the power line characteristic measuring device and the collector unit, wherein the coupler allows a broadband over power line signal to pass from the power line to the collector unit.

5. The apparatus of claim 4, wherein the coupler allows for a representative voltage of the power line to be measured by the power line characteristic measuring device.

6. The apparatus of claim 4, wherein the coupler allows for a representative phase angle of the power line to be measured by the power line characteristic measuring device.

7. The apparatus of claim 4, wherein the coupler allows for a representative current of the power line to be measured by the power line characteristic measuring device.

8. A method of collecting information on characteristics of a power line in a broadband over power line system comprising:
obtaining information on the characteristics of the power line using a collector unit; and
sending the information over the broadband over power line system to a remote location.

9. The method of claim 8, wherein the broadband communication device comprises a regenerator.

10. The method of claim 8, further comprising storing the information on characteristics of the power line in the broadband communication device.

11. The method of claim 8, further comprising collecting the information from data sources comprising a coupler.

12. The method of claim 11, wherein the coupler is capacitive and contains a voltage divider.

13. The method of claim 11, wherein the coupler is inductive.

14. A broadband over power line system for obtaining characteristic data for a power line comprising:
a power line characteristic measuring device for measuring characteristic of the power line;
a regenerator that collects the measurements of the power line characteristic measuring device and sends the measurements over the broadband over power line system to a remote location; and
a coupler to couple the regenerator to the power line to allow the broadband over power line signal to pass from the power line to the regenerator.

15. The system of claim 14, wherein the coupler couples the power line characteristic measuring device to the power line.

16. The system of claim 14, wherein the power line characteristic measuring device is capable of measuring a voltage.

17. The system of claim 14, wherein the power line characteristic measuring device is capable of measuring a phase angle.

18. The system of claim 14, wherein the power line characteristic measuring device is capable of measuring a current.

19. The system of claim 14 wherein the coupler is a capacitive coupler designed as a voltage divider.
